(19) United States
(12) Patent Application Publication
(10) Pub. No.: US 2026/0088789 A1
(43) Pub. Date: Mar. 26, 2026

(54) VARIABLE GAIN AMPLIFIER

(71) Applicant: Infineon Technologies AG, Neubiberg (DE)

(72) Inventor: Marco BUCCI, Graz (AT)

(21) Appl. No.: 18/949,378

(22) Filed: Nov. 15, 2024

Related U.S. Application Data
(60) Provisional application No. 63/698,881, filed on Sep. 25, 2024.

(51) Int. Cl. H03G 3/30

(52) U.S. Cl. CPC H03G 3/3042; H03G 3/3089

(57) ABSTRACT

Devices, systems, and methods for adjustable gain amplification for use in communications systems are described. An amplifier has a gain that is adjustable based on a bias current supplied to the amplifier. The amplifier is configured to operate with a first input saturation level to apply a first gain to an input signal with a first maximum amplitude, and operate with a second input saturation level that is greater than the first input saturation level to apply a second gain smaller than the first gain when the input signal has a second maximum amplitude greater than the first maximum amplitude.

### CROSS-REFERENCE TO RELATED APPLICATIONS

This application claims the benefit of and priority to U.S. provisional application 63/698,881, titled “VARIABLE GAIN AMPLIFIER”, filed Sep. 25, 2024, the entire contents of which are incorporated by reference herein.

### TECHNICAL FIELD OF THE INVENTION

This invention relates generally to communications circuitry, and more specifically to signal amplification in communication systems.

### BACKGROUND

In traditional communications systems, amplifier circuits are commonly employed to amplify an input signal received via an antenna or other source and amplify the input signal such that the input signal may be effectively demodulated, for example to generate digital data that represents information communicated by the input signal.

In some traditional communications systems, variable gain amplifiers are used so that an amount gained applied to an input signal can be varied, for example to adapt signal transmission conditions such as an amplitude of the input signal, an impact of noise, and/or other conditions. In some examples, traditional variable gain amplifiers may be adjustable by varying the magnitude of a bias current supplied to the traditional amplifier.

In some examples, some communications systems operate under challenging conditions in which a magnitude of an input signal is relatively large. In some examples, traditional variable gain amplifiers have characteristics like saturation and/or limited regulation dynamics that render them unsuitable for some applications in which a magnitude of an input signal is relatively large.

### SUMMARY

In some aspects, an input stage of a communications system includes an amplifier configured to operate with a first input saturation level to apply a first gain to an input signal with a first maximum amplitude. The amplifier is configured to operate with a second input saturation level that is greater than the first input saturation level to apply a second gain smaller than the first gain when the input signal has a second maximum amplitude greater than the first maximum amplitude.

In some aspects, a method includes operating with a first input saturation level to apply a first gain to an input signal with a first maximum amplitude. The method further includes operating with a second input saturation level that is greater than the first input saturation level to apply a second gain smaller than the first gain when the input signal has a second maximum amplitude greater than the first maximum amplitude.

In some aspects, an amplifier includes an input configured to receive an input signal from an antenna. The amplifier includes an output configured to generate an output signal after applying an adjustable gain to the input signal based on a bias current. The amplifier is configured to operate with a first input saturation level to apply a first gain to an input signal with a first maximum amplitude. The amplifier is configured to operate with a second input saturation level that is greater than the first input saturation level to apply a second gain smaller than the first gain when the input signal has a second maximum amplitude greater than the first maximum amplitude.

### BRIEF DESCRIPTION OF THE DRAWINGS

FIG. 1 is a block diagram that depicts one example of an input stage of a communications system that includes a variable gain amplifier according to some embodiments

FIG. 2 is a block diagram depicting one example of an input stage of a communications system that includes a variable gain amplifier and a beta multiplier circuit according to some embodiments.

FIG. 3 is a circuit diagram depicting one example of a variable gain amplifier circuit that may be used as part of an input stage of a communications system according to some embodiments.

FIG. 4 is a circuit diagram depicting a beta multiplier circuit according to some embodiments.

FIG. 5 is a plot showing a transfer function of a transconductance amplifier according to some embodiments.

FIG. 6 is a series of plots that depict various signals associated with a variable gain amplifier circuit according to some embodiments.

FIG. 7 shows transient simulation results of an amplitude modulated (AM) demodulator device that includes a variable gain amplifier according to some embodiments.

FIG. 8 is a flow diagram that depicts one example of a method of operating a variable gain amplifier according to some embodiments.

### DETAILED DESCRIPTION

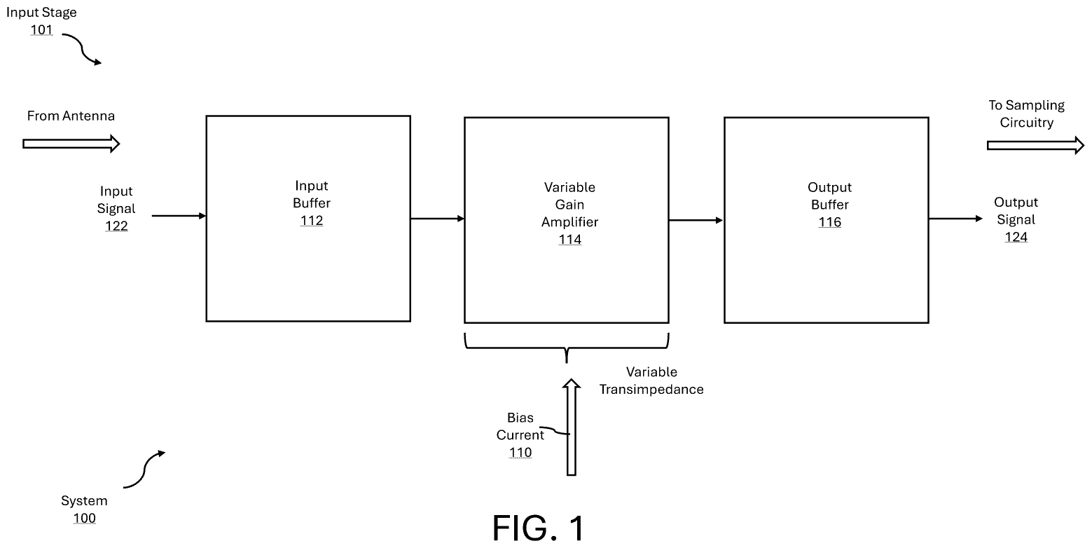

FIG. 1 is a block diagram that depicts one example of an input stage 101 of a communications system 100 that includes a variable gain amplifier 114 according to some embodiments. The input stage 101 may be part of a communications system 100 and serve to receive an input signal from a signal source over a communications channel including for example a wired connection or a wireless antenna. In some examples, the input stage 101 is part of communications circuitry such as near field communication (NFC) communications circuitry that enables devices to exchange data over short distances such as a few centimeters. In other examples, input stage 101 may be part of another type of communications system, such as radio frequency ID (RFID), Bluetooth low energy (BLE), Wireless Lan (i.e., WIFI), Ultra Wideband (UWB) or other type of wired or wireless communications system.

The input stage 101 includes an input buffer 112, an output buffer 116, and a variable gain amplifier 114 between the input buffer 112 and the output buffer 116 and configured to amplify the input signal 122 to generate an output signal 124 that is conditioned for further processing, such as by sampling, demodulation, and/or other circuitry coupled to receive the output signal 124 from the input stage 101. In some examples, the input buffer 112 is configured to attenuate an incoming input signal 122 with a gain that is variable in relatively large steps, the variable gain amplifier 114 is configured to apply a gain that is continually adjustable in relatively smaller steps to the input signal 122, and the output buffer 116 is configured to match the output signal to other downstream circuits and may apply a fixed gain to an output of the variable gain amplifier 114.

Traditional input stages incorporate variable gain amplifiers with a gain that is adjustable based on transconductance gₘ of the amplifier, i.e., by varying the relationship between a voltage V_{IN} of an input signal, and an output current I_{OUT} as shown by the following equation:

$${g}_{m} = {I}_{OUT} / {V}_{IN} \qquad ( 1 )$$

The transconductance gₘ may be measured in siemens (S), which is equivalent to amperes per volt (A/V).

In a traditional transconductance-based amplifier, a gain of the amplifier may be adjustable, for example to maintain a relatively constant output as an amplitude of the input changes, by varying a magnitude of a bias current. According to a traditional gain control amplifier, the amplifier may be operated in a linear operating region to achieve a linear transfer characteristic, meaning that in the linear operating region an amplitude of the amplified output signal changes linearly in response to changes in an amplitude of the input signal. An input saturation level of an amplifier refers to the maximum amplitude of an input signal that can be amplified with a linear transfer characteristic. The input saturation level of an amplifier may be described as a boundary of the linear operating region of the amplifier. If an amplitude (e.g., an absolute value of the amplitude) of the input signal exceeds the input saturation level of the amplifier, the output signal of the amplifier may be clipped or otherwise distorted.

In a traditional automatic gain control amplifier, when the amplitude of an input signal increases, the biasing current supplied to the amplifier is reduced to reduce the gain thus maintaining a substantially constant output amplitude. Reducing the magnitude of the bias current to reduce the gain causes a corresponding reduction to the input saturation level (and the corresponding linear operating region) of a traditional transconductance-based amplifier. As such, a traditional transconductance-based gain control amplifier may be unsuitable for some applications when a maximum amplitude of an input signal is relatively large.

Referring back to FIG. 1, the amplifier 114 is uniquely configured to offer a variable gain for which the input saturation level, which corresponds to a linear operating region of the amplifier 114, may be increased when the maximum amplitude of the input signal 122 increases. In contrast with traditional automatic gain control amplifiers, a gain of the amplifier 114 is configured to be varied by changing a transimpedance Z of the amplifier based on a magnitude of the bias current 110. In some examples, the input signal 122 is a current signal, and the amplifier 114 generates an output signal 124 as a voltage signal with a magnitude dependent on a magnitude of the input current and the magnitude of the bias current 110. In some examples, also in contrast with traditional gain control amplifiers, the amplifier 114 is operable such that an increase in a magnitude of the bias current causes a decrease in the gain applied to the input signal 122. Likewise, the amplifier 114 may also be operable such that a decrease in the magnitude of the bias current causes an increase in the gain applied to the input signal 122.

The transimpedance of amplifier 114 may be described as the ratio of output voltage VOUT of the amplifier 114 relative to an input current IIN of the amplifier according to the following equation.

$${Z}_{t} = {V}_{OUT} / {I}_{IN} \qquad ( 2 )$$

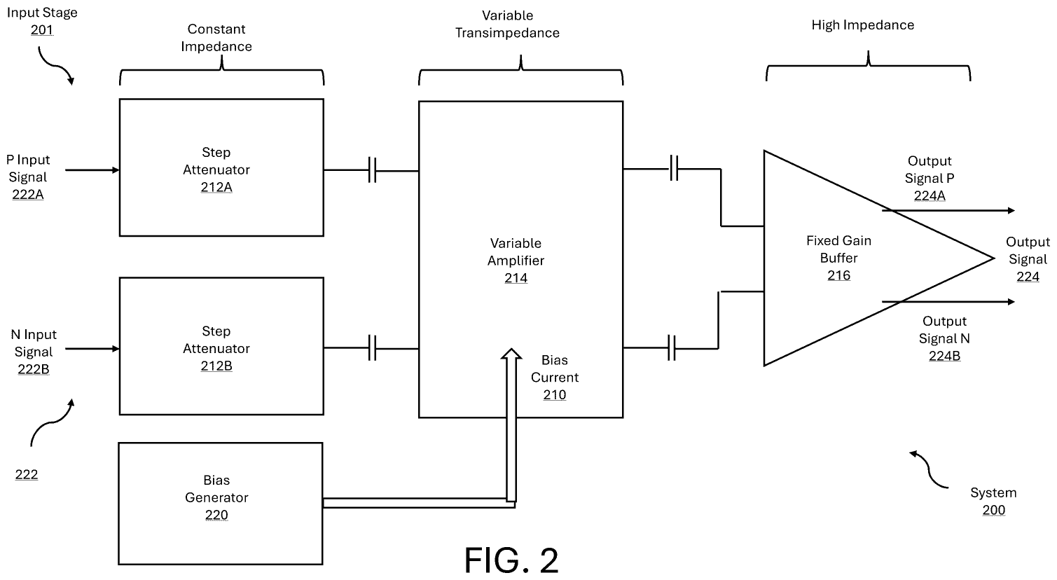

FIG. 2 is a block diagram depicting one example of an input stage 201 of a communications system 200 that includes a variable gain amplifier 214 and a beta multiplier circuit 220 according to some embodiments. As shown in FIG. 1, the input stage 201 includes one or more stepped attenuator(s) 212A, 212B, a variable gain amplifier 214, and a fixed gain buffer 216. The stepped attenuator(s) 212A, 212B are configured to receive complementary signals 222A and 222B of a differential input signal 222 from a signal source such as an antenna or wired communications channel, and attenuate the input signal 222. The stepped attenuator(s) 212A, 212B may match signal levels between the input signal 122 and the output signal 124, for example to prevent distortion and/or overloading. In some examples, the stepped attenuator(s) 212A, 212B may receive the input signal 222 as a voltage signal, and output a current signal to the variable gain amplifier 214. In some examples, the attenuator(s) 212A, 212B may have a substantially higher output impedance than an input impedance of the variable gain amplifier 214, such that a current of the attenuators 212A, 212B output supplied to variable gain amplifier 214 is relatively fixed by the setting of the attenuator. The attenuator(s) 212A, 212B may be configured to attenuate the input signal 222 with a coarse gain adjustment. In one non-limiting example, the attenuator(s) 212A, 212B may attenuate an input signal 222 with a gain of from zero down to a negative gain in steps. As a non-limiting example, the attenuator(s) may be configured to attenuate the input signal 222 in steps of three decibels (dB) such as with a gain selectable from 0, −3, −6 down to −45 dB based on an input code.

The output buffer 216 is a component designed to drive subsequent stages (e.g., further signal conditioning, sampling, demodulation, or other stages) without loading the signal received from the variable gain amplifier 214. In some examples, the output buffer 216 has a substantially higher input impedance than the variable transimpedance variable gain amplifier 214, which may maintain the gain of the amplifier 214 dependent on the transimpedance of the variable gain amplifier 214.

In some examples, input stage 201 is configured such that the stepped attenuator(s) 212A, 212B receive the complementary input signals 222A and 222B as a voltage signal, i.e., a signal where data is represented by a varying voltage. The stepped attenuator(s) 212A, 212B attenuate the complementary input signals 222A, 222B with a coarse gain adjustment in relatively large steps, and convert the input signals 222A and 222B to a current signal, i.e., in which data is represented by a varying current-. According to these examples, the variable gain amplifier 214 is configured to receive the current signal from the stepped attenuator(s) 212A, 212B, and convert the received current signal into a voltage signal, amplified with a variable gain based on a magnitude of the bias current 210.

Like the variable gain amplifier 114 described above with respect to FIG. 1, a gain of the amplifier 214 adjustable by changing a transimpedance of the amplifier 214 as opposed to transconductance as with traditional amplifiers. For example, the gain may be adjustable by selecting a magnitude of a bias current 210 applied to the amplifier 214. The amplifier 214 may be configured to amplify the input signal 222 with a first input saturation level to apply a first gain when the input signal has a first maximum amplitude, and with a second input saturation level larger than the first input saturation level to apply a second gain lower than the first gain when the input signal has a second maximum amplitude greater than the first maximum amplitude. The first input saturation level may correspond to a first linear operating region associated with the first gain, while the second input saturation level corresponds to a second linear operating region associated with the second gain that is larger than the first linear operating region.

In some examples, the amplifier 214 applies the first gain responsive to a bias current 210 with a first magnitude, and the amplifier 214 applies a second gain that is less than the first gain responsive to a bias current 210 with a second magnitude that is greater than the first magnitude. To state it another way, amplifier 214 is uniquely configured to increase the input saturation level of the amplifier 214 when the bias current 210 supplied to the amplifier 214 is increased to reduce a gain of the amplifier.

In some examples, the amplifier 214 may be controllable via a current or voltage source that supplies the bias current 210. In some examples, a bias generator 220 as shown in the FIG. 2 example is configured to generate a bias voltage that causes the bias current 210 to be generated in the amplifier 214. In some examples, bias generator 220 is a circuit configured to generate a stable reference voltage across a wide range of conditions. The bias generator 220 may for example include a beta multiplier circuit that utilizes at least one pair of matched transistors to generate a stable reference voltage with an amplitude based on a resistance across one or more control resistor(s) coupled to the pair of matched transistors. In other examples, the bias generator 220 may include an analog loop based on the amplitude detection of an output (i.e. increasing/decreasing the bias current 210 depending on whether the output is higher/lower than a reference).

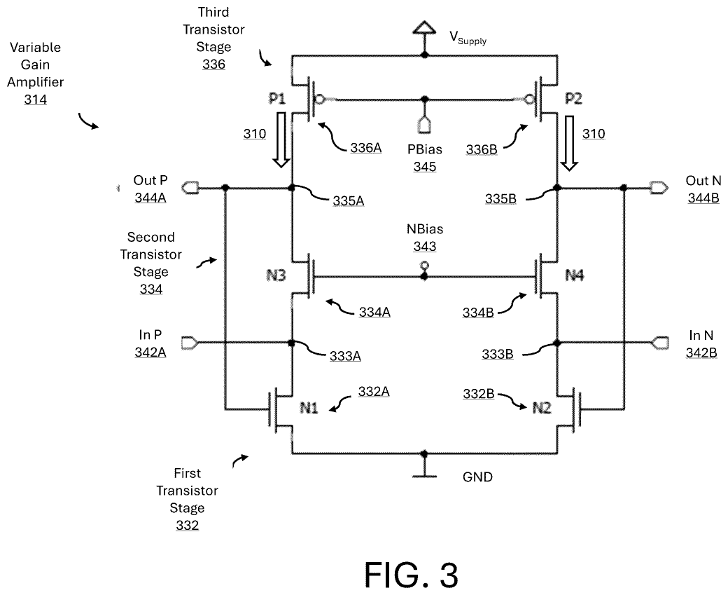

FIG. 3 is a circuit diagram depicting one example of an amplifier circuit 314 with a gain that is adjustable by modifying a variable transimpedance of the amplifier circuit according to some embodiments. The amplifier circuit 314 may be used as part of an input stage 101, 201 of a communications system 100, 200 as depicted in the examples of FIG. 1 and FIG. 2 according to some embodiments. For example, the amplifier circuit 314 may receive an input signal driven from input attenuators 212A and 212B as depicted in FIG. 2. In some examples, amplifier circuit 314 operates as a variable gain amplifier whose gain is proportional to an adjustable transimpedance, in contrast with traditional variable gain amplifiers with a gain is proportional to an adjustable transconductance.

The amplifier circuit 314 depicted in FIG. 3 is configured to amplify a differential input signal 322 received via a pair of inputs 342A, 342B, which are each coupled to transistors of a first transistor stage 332, which has a first pair of transistors including a first transistor 332A and a second transistor 332B. The first pair of transistors 332A, 332B may be matched to one another i.e., the transistors 332A, 332B specifically selected or fabricated to have nearly identical electrical characteristics. As one example, the first pair of transistors 332A, 332B of the first transistor stage 332 may be matched in the sense they are fabricated on the same semiconductor die and/or formed of substantially the same or substantially proportional geometry, doping levels, and/or material properties. In some examples, the first pair of transistors 332A, 332B are selected to minimize variations in parameters such as a threshold voltage (Vth), current gain, temperature coefficient(s), and/or saturation current.

In the example of FIG. 3, the inputs 342A and 342B are coupled to be injected into junctions 333A, 333B between a drain terminal of the first transistor stage 332 and a source terminal of a second transistor stage 334, which has a second pair of transistors including transistors 334A and 334B.

As shown in FIG. 3, the amplifier circuit 314 further includes a pair of outputs 344A and 344B coupled between the second transistor stage 334 and a third transistor stage 336 which has a third pair of transistors including a first transistor 336A, and a second transistor 336B, which may be alternately doped transistors to those of the second transistor stage 334 and the first transistor stage 332. For example, the first transistor stage 332 and the second transistor stage 334 may include N channel transistors, and the third transistor stage 336 includes P channel transistors as shown in the FIG. 3 example. In other examples not depicted, the first transistor stage 332 and second transistor stage 334 may include P channel transistors, and the third transistor stage 336 includes N channel transistors.

As shown in the example of FIG. 3, the pair of outputs 344A and 344B are coupled to the gates of the first pair of transistors 332A, 332B and a junction 335A, 335B between the third transistor stage 336 and the second transistor stage 334, specifically to a junctions 335A, 335B between the drain terminals of the second pair of transistors 334A, 334B and the drain terminals of the third pair of transistors 336A, 336B. As shown in FIG. 3, the source terminals of the third pair of transistors 336A, 336B are coupled to a supply voltage Vsupply, and the source terminals of the first transistor stage 332 are coupled to a ground reference GND.

As shown in the FIG. 3 example, the respective gate terminals of the second transistor stage 334 are coupled together to a bias input 343, and the respective gate terminals of the third transistor stage 336 are coupled together to a bias input 345. According to one example, the bias input 345 may be coupled to a bias voltage, such as the output of a beta multiplier circuit 220 as shown in FIG. 2, that causes a bias current 310 to be generated by the third transistor stage 336 as shown in FIG. 3. In some examples, the bias input 343 may be coupled to a current mirrored from the bias voltage from the beta multiplier circuit 220. In some examples, the bias input 343 operates to fix a voltage at junctions 333A and 333B such that the N1-N4 transistors 332A, 332B and 334A, 334B are operated in saturation.

According to the example of FIG. 3, a gain of the amplifier circuit 314 is adjustable based modifying a transimpedance of the amplifier circuit 314 based on a magnitude of the bias current 310. Accordingly, the amplifier circuit 314 is uniquely configured to linearly amplify an input signal with a relatively large maximum amplitude with little or no distortion.

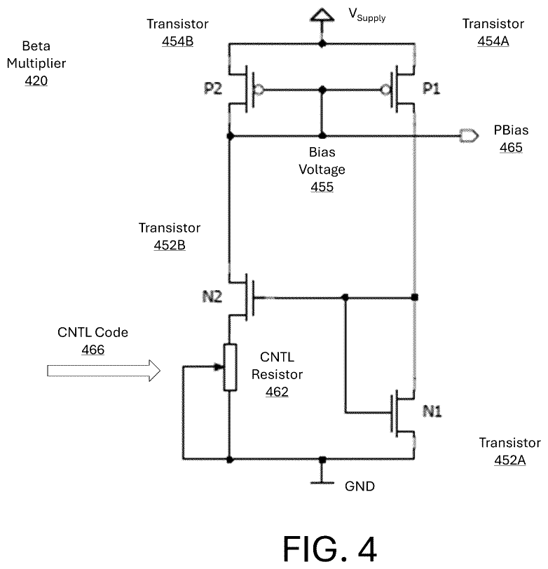

FIG. 4 is a circuit diagram depicting a beta multiplier circuit 420 according to some embodiments. The beta multiplier circuit 420 functions as a current source used to generate a stable and variable bias current 310 to specify a gain of a variable gain amplifier circuit 314 as shown in the example of FIG. 3. As shown in the FIG. 4 example, the beta multiplier circuit 420 includes a first transistor pair including an N1 transistor 452A and an N2 transistor 452B, and a second transistor pair including a P1 transistor 454A and a P2 transistor 454B. The N1 transistor 452A may be matched to the N2 transistor 452B. The P1 transistor 454A may be matched to the P2 transistor 454B as well. In some examples, where the beta multiplier circuit 420 is used to generate a bias current 310 for a variable gain amplifier circuit 314 as shown in FIG. 3 (e.g., supplied to the bias input 345), the first transistor pair 452A, 452B of the beta multiplier circuit 420 are matched with the first pair of transistors 332A, 332B of the first transistor stage 332 of the amplifier circuit 314. In some examples, the P1 transistor 454A and the P2 transistor 454B may be matched with the third transistor pair 336A, 336B of the third transistor stage 336 of the amplifier circuit 314.

In the example of FIG. 4, the first transistor pair 452A, 452B are N channel transistors and the second transistor pair 454A, 454B are P channel transistors. In other examples not depicted, the first transistor pair 452A, 452B, may instead be P channel transistors and the second transistor pair 454A, 454B may be N channel transistors.

As shown in FIG. 4, the first transistor pair includes an N1 transistor 452A with a source terminal coupled to a ground reference, and drain and gate terminals coupled to one another and a gate of an N2 transistor 452B. The gate of the N2 transistor 452B and the gate and drain terminals of the N1 transistor 452A are coupled to a drain terminal of the P1 transistor 454A of the second transistor pair 454A, 454B. The P1 transistor 454A and P2 transistor 454B each have a source terminal coupled to a supply input Vsupply. The gates of the P1 transistor 454A and the P2 transistor 454B are coupled to one another and a drain terminal of the P2 transistor 454B, which is coupled to a drain terminal of the N2 transistor 452B. A source terminal of the N2 transistor 452B is coupled to a first end of one or more control resistor(s) 462, which has a second end coupled to a ground reference GND. A resistance of the control resistor(s) 462 is selectable based on the value of a control code 466 which specifies a resistance of the control resistor(s) 462. An output 465 of the beta multiplier circuit 420 is coupled to a junction between the drain terminal of the N2 transistor 452B and the drain terminal of the P2 transistor 454B, as well as the gate terminals of the P1 454A transistor and the P2 454B transistor.

The beta multiplier circuit 420 depicted in FIG. 4 is configured to generate an output signal at the bias output 465 with a stable voltage with a magnitude that is adjustable, or selectable, based on a control code 466 applied to the control resistor 462. In some examples, if a ratio between the N2 452B transistor and the N1 transistor 452A of the beta multiplier circuit 420 is around 4, (e.g., the transistor N2 452B has a size four times as large as the N1 transistor 452A), a transconductance gmNI of the N1 transistor may be expressed by the following equation:

$${g}_{m} N 1 = 1 / {R}_{ctrl} \qquad ( 3 )$$

Accordingly, if the N1 transistor 332A and the N2 transistor 332B of the first transistor stage 332 of the amplifier circuit 314 depicted in the FIG. 3 example are selected to match the N1 462A transistor and/or the N2 462B transistor of the beta multiplier circuit 420, then the gain of the amplifier circuit 314 is controlled based on a resistance value of the control resistor(s) 462 of the beta multiplier circuit 420.

In some examples, a resistance of the control resistor(s) 462 is selectable based on a control code 466. In some examples, the control code 466 specifies one of a plurality of substantially logarithmic settings for the control resistor(s) 462.

Table 1 below depicts one non-limiting example of settings that may be applied to a stepped attenuator a variable gain amplifier according to some embodiments. The example of Table 1 shows a code that specifies a selectable gain, or attenuation, applied to an input signal 222 by a stepped attenuator(s) 212A, 212B, and a variable gain applied by a variable gain amplifier 214, such as the amplifier circuit 314 shown in FIG. 3.

As shown in Table 1, the attenuator(s) 212A, 212B are configured to attenuate an input signal 222 with one of three states dependent on a value of an attenuation code with a value of 0, 1 or 2. When a code with a value of zero is applied, the stepped attenuator(s) 212A, 212B attenuate the input signal with a gain of 0 dB (i.e., does not attenuate the input signal). When a code with a value of 1 is applied, the stepped attenuator(s) 212A, 212B attenuates the input signal 222 with a gain of −3 dB. When a code with a value of 2 is applied, the stepped attenuator(s) 212A, 212B attenuates the input signal 222 with a gain of −6 dB.

TABLE 1

| | | |
|---|---|---|
| Attenuation | Amplification | Global Gain |

| code | dB | code | dB | dB |
|---|---|---|---|---|
| 0 | 0 | 124 | +6 | +6 |
| 1 | −3 | 124 | +6 | +3 |
| 0 | 0 | 62 | 0 | 0 |
| 2 | −6 | 124 | +6 | 0 |
| 1 | −3 | 62 | 0 | −3 |
| 0 | 0 | 0 | −6 | −6 |
| 2 | −6 | 62 | 0 | −6 |
| 1 | −3 | 0 | −6 | −9 |
| 2 | −6 | 0 | −6 | −12 |

As also shown in Table 1, the amplifier 214 has a gain that is also selectable among three values, 0, 62, and 124. The three values may be described as logarithmic as they represent exponential values in the Table 1 example.

As shown by the example of Table 1, a global gain of the input stage 201 depicted in FIG. 2 may be selected by the respective codes applied to the stepped attenuator(s) 212A, 212B and the amplifier 214, and in some examples may range from a positive gain applied to the input signal and a negative gain applied to the input signal 222. For example, a code of zero applied to the stepped attenuator(s) 212A, 212B and a code of 124 applied to the amplifier 214 causes a global gain of +6 dB. As another example, a code of zero applied to the stepped attenuator(s) 212A, 212B and a code of 0 applied to the amplifier 214 causes a global gain of −6 dB. In some examples, different code combinations may be selected to achieve the same global gain, for example a code of zero applied to the stepped attenuator(s) 212A, 212B and a code of 62 applied to the amplifier 214 causes a global gain of 0 dB, and a code of 2 applied to the stepped attenuator(s) 212A, 212B and a code of 124 applied to the amplifier 214 causes the same global gain of 0 dB.

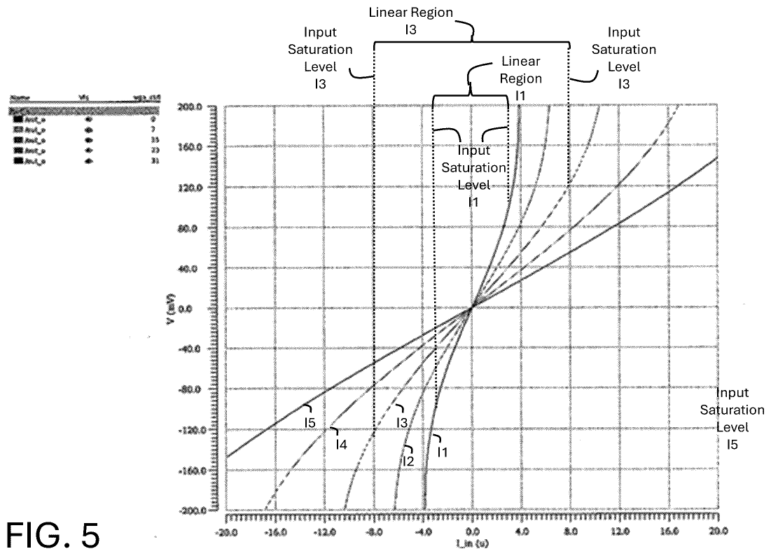

FIG. 5 is a plot showing a transfer function of a transconductance amplifier according to some embodiments. The example of FIG. 5 shows an input current of the amplifier 214 along the horizontal x-axis vs an output voltage of the amplifier 214 along the vertical y-axis. The example of FIG. 5 shows five plots I1-I5 that correspond to different bias currents 210 applied to the amplifier 214. Referring to the example of FIG. 3, the bias currents may be applied to the bias input 345 of the amplifier circuit 314 to control a gain of the amplifier circuit 314.

In FIG. 5, the plot I1 represents a relatively small bias current around 4 microamps, which may correspond to a control signal 31 applied to control resistor 262 of the beta multiplier circuit 220. The plot I2 represents a bias current around 6 microamps, which may correspond to a control signal representing a code of 23 or 24 applied to control resistor 262. The plot I3 represents a bias current around 10 microamps, which may correspond to a control signal representing a code of 15 or 16 applied to control resistor 262. The plot I4 represents a bias current around 18 microamps, which may correspond to a control signal representing a code of 7 or 8 applied to control resistor 262. The plot I5 represents a bias current greater than 20 microamps, which may correspond to a control signal representing a code of 0 applied to control resistor 262.

An input saturation level of each plot represents a boundary to the range of input current magnitudes, i.e., between a maximum positive value and a minimum negative value of an input current, that the amplifier 214 is operable to amplify in with a linear relationship between the input current and the output voltage. For ease of illustration and clarity, the input saturation levels and corresponding linear operating regions of only the respective I1 and I3 plots are labeled in the FIG. 5 diagram. As shown in FIG. 5, the input saturation level (and the linear operating region) of the I3 plot, which corresponds to a bias current greater than 10 microamps, is larger than the input saturation level (and the linear operating region) of the I1 plot, which corresponds to a bias current around 4 microamps. As such, in contrast with a traditional transconductance amplifier, the input saturation level of amplifier 214 increases with an increased bias current 210, and the gain of the amplifier 214, represented by a slope of the respective I1-I5 plots, decreases with an increase in bias current 210. Accordingly, amplifier 214 may be particularly suitable to amplify input signals 222 when a maximum amplitude (e.g., a maximum absolute value) of an input signal is relatively large, such as part of an input stage 201 of a communications system 200 like an NFC communications system.

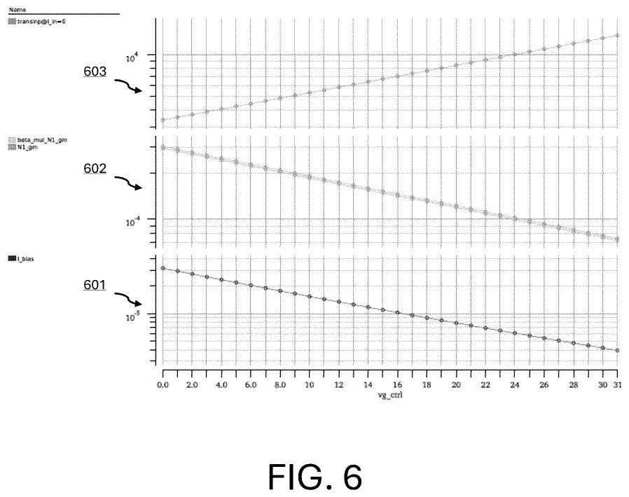

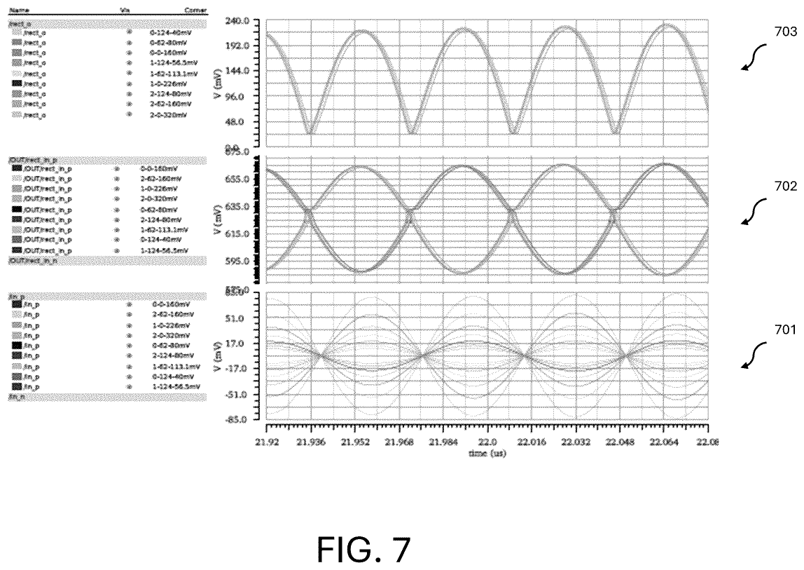

FIG. 6 is a series of plots 601-603 that depict various signals associated with a variable gain amplifier circuit 314 as shown in the FIG. 3 circuit according to some embodiments. In FIG. 6, a plot 601 shows a bias current 220 decreasing as a control code 466 applied to a beta multiplier circuit 420 increases from a value of 0 to a value of 31. Plot 602 shows the gain associated with the N1 transistor (labeled beta1_mul_N1_gm) 462A of the beta multiplier circuit 420 and the N1 transistor 332A (labeled N1_gm) of the amplifier 214 decreasing as the bias current 220 decreases. Plot 603 shows the transimpedance of the amplifier 214 increasing as the bias current 220 decreases. In some examples, a gain of the amplifier 214 corresponds to an inverse of the gain of the N1 transistor 332A N1_gₘ according to the equation g_{m-Amplifier}=1/N1_gₘ. Accordingly, plot 602 of FIG. 6 demonstrates that a gain of the amplifier 214 increases responsive to a decrease in the bias current 220. FIG. 7 shows transient simulation results of an amplitude modulated (AM) demodulator device that includes a variable gain amplifier such as amplifier circuit 314 depicted in FIG. 3 according to some embodiments. The example of FIG. 7 includes a plot 701 that depicts a plurality of input signals that vary from a minimum input voltage of about 9 millivolts peak-to-peak (mVpp) to a maximum input voltage of 76 mVpp. Plot 702 shows a demodulator output signal, and plot 703 shows a rectified version of the demodulator output signal. In some examples, a gain resolution of an amplifier circuit 314 may be improved by using a dithering technique applied to control resistor(s) 462, which may result in a resolution of 0.1 dB per step. The amplification code values in Table 1 above may correspond to the respective codes represented in FIGS. 5-7 without using a dithering technique, and as such are 4 times the value of their counterparts depicted in FIGS. 5-7. Accordingly, the amplification code 124 in Table 1 may correspond to the code value 31 in FIGS. 5 and 6, and the amplification code 62 in Table 1 may correspond to a code value of around 15.5 in FIGS. 5 and 6 in some embodiments.

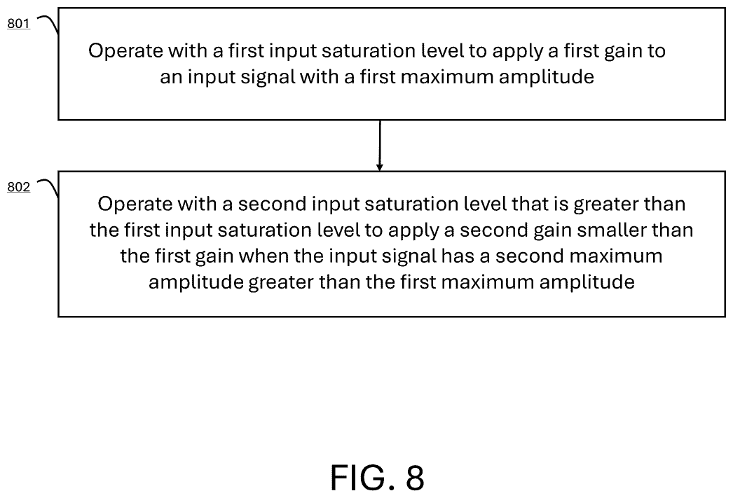

FIG. 8 is a flow diagram that depicts one example of a method of operating a variable gain amplifier according to some embodiments. As shown in FIG. 8, at 801, the method includes operating with a first input saturation level to apply a first gain to an input signal 122 with a first maximum amplitude. As also shown in FIG. 8, at 802, the method further includes operating with a second input saturation level that is greater than the first input saturation level to apply a second gain smaller than the first gain when the input signal 122 has a second maximum amplitude greater than the first maximum amplitude. In some examples, the method further includes adjusting a gain of the amplifier by varying a transimpedance of the amplifier 114 based on a magnitude of the bias current 110. In some examples, the method includes increasing the magnitude of the bias current to decrease to a gain of the amplifier. In some examples, the method further includes decreasing the magnitude of the bias current to increase the gain of the amplifier.

In some examples, the method further includes varying the transimpedance of the amplifier 114 by varying a voltage level of an output signal 124 relative to a current level of the input signal 122. In some examples, the method further includes generating a bias voltage 455 with a beta multiplier circuit 420 that causes the bias current 310 to have the first magnitude or the second magnitude based on a control code 466 with one of a plurality of discrete, logarithmic values.

In some examples, the method further includes selecting the first magnitude or the second magnitude responsive to a magnitude of the input signal 122. In some examples, the method further includes receiving an input signal at junctions 333A, 333B between drain terminals of a first pair of transistors 332A, 332B of a first transistor stage 332 and source terminals of a second pair of transistors 334A, 334B of a second transistor stage 334 coupled in series with the first pair of transistors 332A, 332B. In some examples, the method further includes receiving a bias signal at a bias input 343 at gate terminals of the second pair of transistors 334A, 334B. In some examples, the method further includes receiving a bias signal at a bias input 345 at gate terminals of a third pair of transistors 336A, 336B of a third transistor stage 336 coupled in series with the second pair of transistors 334A, 334B, wherein the third transistor stage 336 generates the bias current 310 based on a reference voltage received at the bias input 345.

### CLAUSES

Clause 1. An input stage of a communications system, comprising: an amplifier configured to: operate with a first input saturation level to apply a first gain to an input signal with a first maximum amplitude; and operate with a second input saturation level that is greater than the first input saturation level to apply a second gain smaller than the first gain when the input signal has a second maximum amplitude greater than the first maximum amplitude.
Clause 2. The input stage of clause 1, wherein a gain of the amplifier is adjustable by varying a transimpedance of the amplifier based on a magnitude of the bias current.
Clause 3. The input stage of clause 2, wherein varying the transimpedance of the amplifier comprises varying a voltage level of an output signal relative to a current level of the input signal.
Clause 4. The input stage of any of clauses 1-3, wherein the amplifier is configured such that an increase in the magnitude of the bias current causes a decrease to a gain of the amplifier.
Clause 5. The input stage of any of clauses 1-4, wherein the input stage further comprises: a beta multiplier circuit configured to generate a bias voltage that causes the bias current to have the first magnitude or the second magnitude based on a control code with one of a plurality of discrete, logarithmic values.
Clause 6. The input stage of clause 5, wherein the bias current is selectable between the first magnitude and the second magnitude responsive to a magnitude of the input signal.
Clause 7. The input stage of any of clauses 1-6, wherein the amplifier comprises: a first transistor stage comprising a first pair of transistors; a second transistor stage comprising a second pair of transistors connected in series with the first pair of transistors; a third transistor stage comprising a third pair of transistors coupled in series with the second pair of transistors; a pair of inputs at junctions between drain terminals of the first pair of transistors and source terminals of the second pair of transistors.
Clause 8. A method, comprising: operating with a first input saturation level to apply a first gain to an input signal with a first maximum amplitude; and operating with a second input saturation level that is greater than the first input saturation level to apply a second gain smaller than the first gain when the input signal has a second maximum amplitude greater than the first maximum amplitude.
Clause 9. The method of clause 8, further comprising: adjusting a gain of the amplifier by varying a transimpedance of the amplifier based on a magnitude of the bias current.
Clause 10. The method of clause 9, wherein varying the transimpedance of the amplifier comprises varying a voltage level of an output signal relative to a current level of the input signal.
Clause 11. The method of any of clauses 8-10, further comprising: increasing the magnitude of the bias current to decrease to a gain of the amplifier.
Clause 12. The method of any of clauses 8-11, further comprising: generating a bias voltage with beta multiplier circuit that causes the bias current to have the first magnitude or the second magnitude based on a control code with one of a plurality of discrete, logarithmic values.
Clause 13. The method of any of clauses 8-12, further comprising: selecting the first magnitude or the second magnitude responsive to a magnitude of the input signal.
Clause 14. The method of any of clauses 8-13, further comprising: receiving the input signal at junctions between drain terminals of a first pair of transistors of a first transistor stage and source terminals of a second pair of transistors of a second transistor stage coupled in series with the first pair of transistors.
Clause 15. An amplifier, comprising, comprising: an input configured to receive an input signal from an antenna; an output configured to generate an output signal after applying an adjustable gain to the input signal based on a bias current; and wherein the amplifier is configured to: operate with a first input saturation level to apply a first gain to an input signal with a first maximum amplitude; and operate with a second input saturation level that is greater than the first input saturation level to apply a second gain smaller than the first gain when the input signal has a second maximum amplitude greater than the first maximum amplitude.
Clause 16. The amplifier of clause 15, wherein a gain of the amplifier is adjustable by varying a transimpedance of the amplifier based on a magnitude of the bias current.
Clause 17. The input stage of clause 16, wherein varying the transimpedance of the amplifier comprises varying a voltage level of an output signal relative to a current level of the input signal.
Clause 18. The amplifier of any of clauses 15-17, wherein the amplifier is configured such that an increase in the magnitude of the bias current causes a decrease to a gain of the amplifier.
Clause 19. The amplifier of any of clauses 15-18, further comprising: a beta multiplier circuit configured to generate a bias voltage that causes the bias current to have the first magnitude or the second magnitude based on a control code with one of a plurality of discrete, logarithmic values.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

1. An input stage of a communications system, comprising:
an amplifier configured to:
operate with a first input saturation level to apply a first gain to an input signal with a first maximum amplitude; and
operate with a second input saturation level that is greater than the first input saturation level to apply a second gain smaller than the first gain when the input signal has a second maximum amplitude greater than the first maximum amplitude.

2. The input stage of claim 1, wherein a gain of the amplifier is adjustable by varying a transimpedance of the amplifier based on a magnitude of the bias current.

3. The input stage of claim 2, wherein varying the transimpedance of the amplifier comprises varying a voltage level of an output signal relative to a current level of the input signal.

4. The input stage of claim 1, wherein the amplifier is configured such that an increase in the magnitude of the bias current causes a decrease to a gain of the amplifier.

5. The input stage of claim 1, wherein the input stage further comprises:
a beta multiplier circuit configured to generate a bias voltage that causes the bias current to have the first magnitude or the second magnitude based on a control code with one of a plurality of discrete, logarithmic values.

6. The input stage of claim 5, wherein the bias current is selectable between the first magnitude and the second magnitude responsive to a magnitude of the input signal.

7. The input stage of claim 1, wherein the amplifier comprises:
a first transistor stage comprising a first pair of transistors;
a second transistor stage comprising a second pair of transistors connected in series with the first pair of transistors;
a third transistor stage comprising a third pair of transistors coupled in series with the second pair of transistors;
a pair of inputs at junctions between drain terminals of the first pair of transistors and source terminals of the second pair of transistors.

8. A method, comprising:
operating with a first input saturation level to apply a first gain to an input signal with a first maximum amplitude; and
operating with a second input saturation level that is greater than the first input saturation level to apply a second gain smaller than the first gain when the input signal has a second maximum amplitude greater than the first maximum amplitude.

9. The method of claim 8, further comprising:
adjusting a gain of the amplifier by varying a transimpedance of the amplifier based on a magnitude of the bias current.

10. The method of claim 9, wherein varying the transimpedance of the amplifier comprises varying a voltage level of an output signal relative to a current level of the input signal.

11. The method of claim 8, further comprising:
increasing the magnitude of the bias current to decrease to a gain of the amplifier.

12. The method of claim 11, further comprising:
generating a bias voltage with beta multiplier circuit that causes the bias current to have the first magnitude or the second magnitude based on a control code with one of a plurality of discrete, logarithmic values.

13. The method of claim 11, further comprising:
selecting the first magnitude or the second magnitude responsive to a magnitude of the input signal.

14. The method of claim 11, further comprising:
receiving the input signal at junctions between drain terminals of a first pair of transistors of a first transistor stage and source terminals of a second pair of transistors of a second transistor stage coupled in series with the first pair of transistors.

15. An amplifier, comprising, comprising:
an input configured to receive an input signal from an antenna;
an output configured to generate an output signal after applying an adjustable gain to the input signal based on a bias current; and
wherein the amplifier is configured to:
operate with a first input saturation level to apply a first gain to an input signal with a first maximum amplitude; and
operate with a second input saturation level that is greater than the first input saturation level to apply a second gain smaller than the first gain when the input signal has a second maximum amplitude greater than the first maximum amplitude.

16. The amplifier of claim 15, wherein a gain of the amplifier is adjustable by varying a transimpedance of the amplifier based on a magnitude of the bias current.

17. The input stage of claim 16, wherein varying the transimpedance of the amplifier comprises varying a voltage level of an output signal relative to a current level of the input signal.

18. The amplifier of claim 15, wherein the amplifier is configured such that an increase in the magnitude of the bias current causes a decrease to a gain of the amplifier.

19. The amplifier of claim 15, further comprising:
a beta multiplier circuit configured to generate a bias voltage that causes the bias current to have the first magnitude or the second magnitude based on a control code with one of a plurality of discrete, logarithmic values.
